(19) United States
(12) Patent Application Publication
(10) Pub. No.: US 2024/0292589 A1
(43) Pub. Date: Aug. 29, 2024

(54) COMPONENT MOUNTING MACHINE

(71) Applicant: FUJI CORPORATION, Chiryu (JP)

(72) Inventor: Tomoya FUJIMOTO, Nagoya-shi (JP)

(73) Assignee: FUJI CORPORATION, Chiryu (JP)

(21) Appl. No.: 18/573,202

(22) PCT Filed: Jun. 30, 2021
(86) PCT No.: PCT/JP2021/024807

§ 371 Date: Dec. 21, 2023

(51) Int. Cl. H05K 13/08

(52) U.S. Cl. CPC H05K 13/0812

(57) ABSTRACT

A component mounting machine of the present disclosure includes a control section to cause an illumination section and an imaging section to capture an image of a component-absent state and an image of the component-present state under multiple different illumination conditions, calculate a similarity between the image of the component-absent state and the image of the component-present state for each illumination condition, and set an illumination condition for inspection used in execution of inspection of the target component, based on the similarity. The control section sets an illumination condition in which the similarity is lowest, among the multiple different illumination conditions, as the illumination condition for inspection, when setting the illumination condition for inspection based on the similarity.

### TECHNICAL FIELD

The present disclosure relates to a component mounting machine.

### BACKGROUND ART

Conventionally, there is known a component mounting machine including a control section that determines an arrangement state of a component using an image of a board captured by a mark camera provided in the component mounting machine. For example, Patent Literature 1 discloses a component mounting machine including a control section that captures an image of a board using a mark camera in a state where the board is irradiated with light under a predetermined illumination condition, calculates brightness of a designated area of the image, and determines an arrangement state of a component based on the brightness.

### PATENT LITERATURE

Patent Literature 1: International Publication WO2016/174763

### BRIEF SUMMARY

### Technical Problem

In such a component mounting machine, component presence/absence inspection of determining whether the component is mounted on the board may be executed using the image captured by the mark camera. The component presence/absence inspection is executed as follows, for example. That is, first, a component-absent image in a state where the component is absent in a predetermined area of the board and a component-present image in a state where the component is present in the predetermined area of the board are captured. Next, an inspection image of a predetermined area of an inspection target board is captured. Next, a similarity between the state where the component is absent in the predetermined area of the board and the state of the predetermined area of the inspection target board is calculated using the component-absent image and the inspection image, and a similarity between the state where the component is present in the predetermined area of the board and the state of the predetermined area of the inspection target board is also calculated using the component-present image and the inspection image. Then, when the similarities are compared, in a case where the similarity between the state where the component is present in the predetermined area of the board and the state in the predetermined area of the inspection target board is higher than the similarity between the state where the component is absent in the predetermined area of the board and the state in the predetermined area of the inspection target board, it is determined that the component is present in the predetermined area of the inspection target board, and in the opposite case, it is determined that the component is absent in the predetermined area of the inspection target board. The illumination condition for capturing the image is set by an operator.

However, an appropriate illumination condition may be changed depending on a combination of a pattern of the board and a component type. In addition, in a case where mounting positions on the board are different even for the same component, an appropriate illumination condition may be changed. Therefore, it is not easy for the operator to set an appropriate illumination condition for any component.

The present disclosure has been made to solve the above-described problems, and a main object thereof is to easily set an appropriate illumination condition.

### Solution to Problem

A component mounting machine of the present disclosure is a component mounting machine for mounting components on a board, the component mounting machine including an illumination section configured to irradiate the board with light under multiple different illumination conditions, an imaging section configured to capture an image of the board from above the board, and a control section configured to, in a case where one of the components is defined as a target component, an area in which the target component is mounted on the board is defined as a target area, a state where the target component is absent in the target area is defined as a component-absent state, and a state where the target component is present in the target area is defined as a component-present state, cause the illumination section and the imaging section to capture an image of the component-absent state and an image of the component-present state under the multiple different illumination conditions, calculate a similarity between the image of the component-absent state and the image of the component-present state for each illumination condition, and set an illumination condition for inspection used in execution of inspection of the target component, based on the similarity, in which the control section is configured to, when setting the illumination condition for inspection based on the similarity, among the multiple different illumination conditions, set an illumination condition in which the similarity is lower than a predetermined similarity as the illumination condition for inspection, set an illumination condition in which the similarity is lowest as the illumination condition for inspection, or set an illumination condition in which the similarity is lower than the predetermined similarity and is lowest as the illumination condition for inspection.

In this component mounting machine, when the illumination condition for inspection is set based on the similarity, among the multiple different illumination conditions, the illumination condition in which the similarity is lower than the predetermined similarity is set as the illumination condition for inspection, the illumination condition in which the similarity is lowest is set as the illumination condition for inspection, or the illumination condition in which the similarity is lower than the predetermined similarity and is lowest is set as the illumination condition for inspection. In a case where the illumination condition in which the similarity is high is set as the illumination condition for inspection, it may be impossible to perform, with high accuracy, a determination whether the image captured when the inspection of the target component is executed is close to the image of the component-present state or the image of the component-absent state. Here, since the illumination condition in which the similarity is lower than the predetermined similarity, the illumination condition in which the similarity is lowest, or the illumination condition in which the similarity is lower than the predetermined similarity and the similarity is lowest is set as the illumination condition for inspection, such a determination can be performed with high accuracy. Further, since it is not necessary for an operator to set the illumination condition for inspection, a work burden is not imposed on the operator. Therefore, an appropriate illumination condition for inspection can be easily set.

### BRIEF DESCRIPTION OF DRAWINGS

FIG. 1 is a diagram schematically illustrating a configuration of component mounting machine 10.

FIG. 2 is a diagram schematically illustrating a configuration of mark camera 50.

FIG. 3 is an A-view of epi-illumination 53.

FIG. 4 is a B-view of side-illumination 55.

FIG. 5 is a block diagram illustrating an electric connection relationship of component mounting machine 10.

FIG. 6 is a flowchart illustrating an example of a component presence/absence inspection routine.

FIG. 7 is a diagram illustrating an example of data for inspection 63a.

FIG. 8 is a diagram illustrating a component presence/absence inspection result table.

FIG. 9 is a flowchart illustrating an example of a pre-inspection processing routine.

FIG. 10 is a flowchart illustrating an example of the pre-inspection processing routine.

FIG. 11 is a diagram illustrating an example of an image obtained by imaging a target area under a first illumination condition.

FIG. 12 is a diagram illustrating an example of an image obtained by imaging the target area under a second illumination condition.

FIG. 13 is a diagram illustrating a similarity.

### DESCRIPTION OF EMBODIMENTS

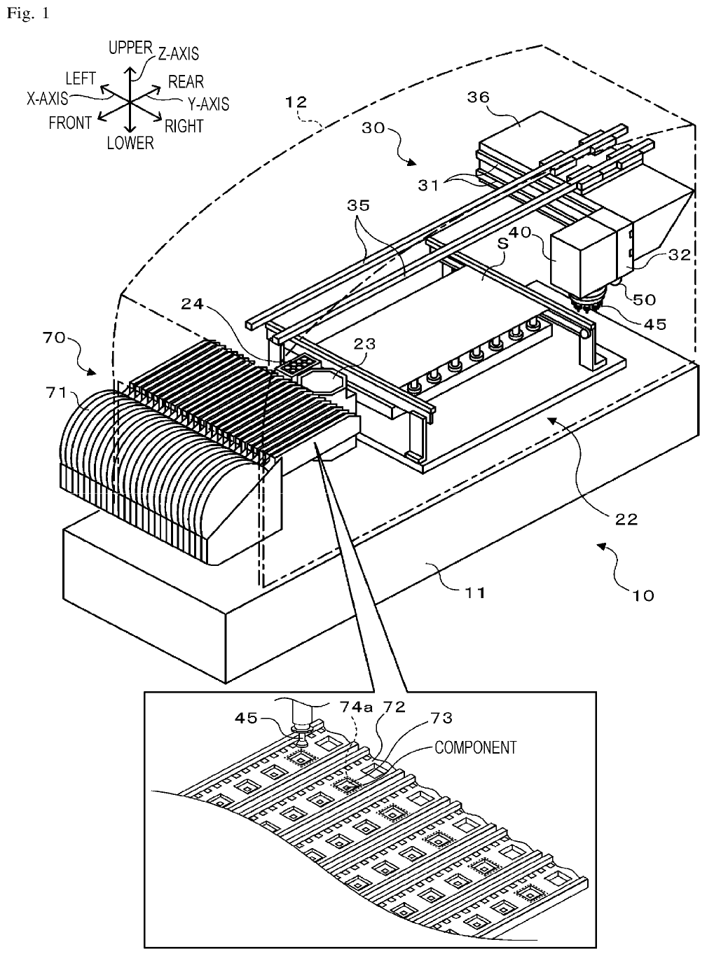

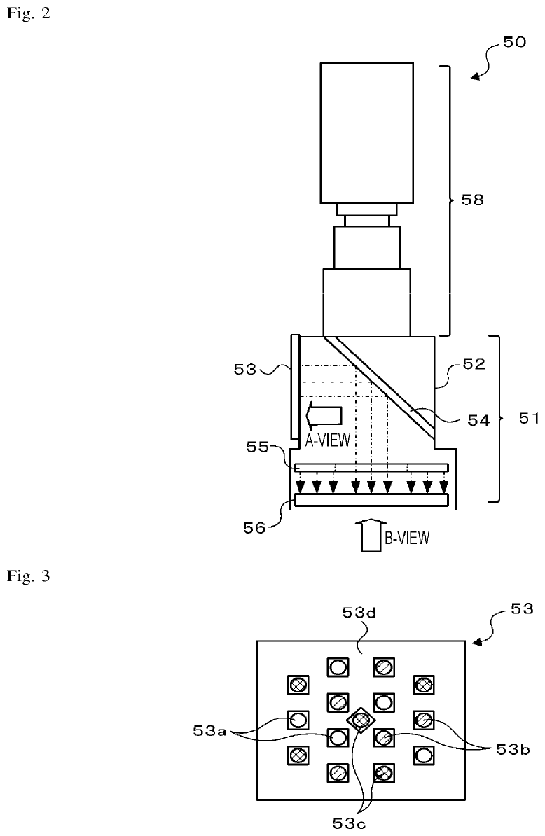

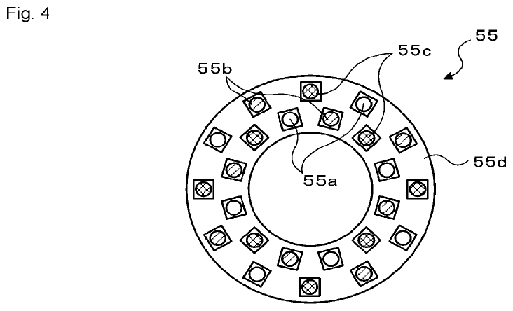

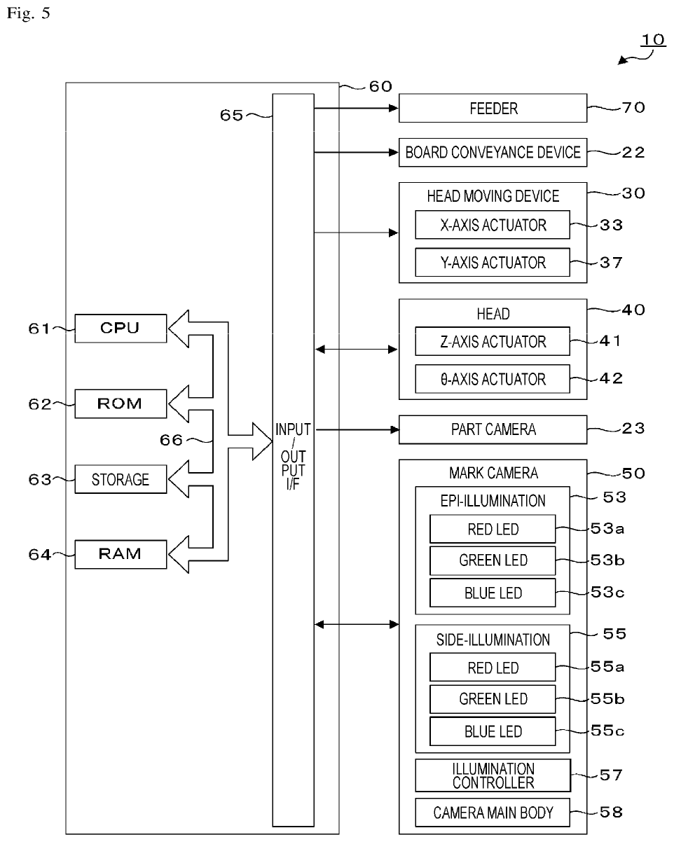

A preferred embodiment of the present disclosure will be described below with reference to the accompanying drawings. FIG. 1 is a diagram schematically illustrating a configuration of component mounting machine 10, FIG. 2 is a diagram schematically illustrating a configuration of mark camera 50, FIG. 3 is an A-view of epi-illumination 53, FIG. 4 is a B-view of side-illumination 55, and FIG. 5 is a block diagram illustrating an electric connection relationship of component mounting machine 10. In the present embodiment, a left-right direction (X-axis direction), a front-rear direction (Y-axis direction), and an up-down direction (Z-axis direction) are as illustrated in FIG. 1.

As illustrated in FIG. 1, component mounting machine 10 includes board conveyance device 22 that conveys board S, head 40 that picks up a component using suction nozzle 45 to mount the component on board S, head moving device 30 that moves head 40 in the X-axis direction and the Y-axis direction, mark camera 50 that images board S, and feeder 70 that supplies the component to head 40. These elements are accommodated in casing 12 installed on base 11. In addition to these elements, component mounting machine 10 also includes part camera 23 that images the component picked up by head 40, nozzle station 24 that accommodates suction nozzle 45 for exchange, or the like. Multiple component mounting machines 10 are arranged side by side in a board conveyance direction (X-axis direction) to make up a production line.

Board conveyance device 22 is installed on base 11. Board conveyance device 22 includes a pair of conveyor rails, which are arranged at intervals in the Y-axis direction, and conveys board S from the left to the right (board conveyance direction) in FIG. 1 by driving the pair of conveyor rails.

As illustrated in FIG. 1, head moving device 30 includes pair of X-axis guide rails 31, X-axis slider 32, X-axis actuator 33 (see FIG. 5), pair of Y-axis guide rails 35, Y-axis slider 36, and Y-axis actuator 37 (see FIG. 5). Pair of Y-axis guide rails 35 are installed on an upper stage in casing 12 to extend in parallel to each other in the Y-axis direction. Y-axis slider 36 extends to span pair of Y-axis guide rails 35 and moves in the Y-axis direction along Y-axis guide rails 35 by the driving of Y-axis actuator 37. Pair of X-axis guide rails 31 are installed on a front surface of Y-axis slider 36 to extend in parallel to each other in the X-axis direction. X-axis slider 32 extends to span pair of X-axis guide rails 31 and moves in the X-axis direction along X-axis guide rails 31 by the driving of X-axis actuator 33. Head 40 is attached to X-axis slider 32, and head moving device 30 moves head 40 in the X-axis direction and the Y-axis direction by moving X-axis slider 32 and Y-axis slider 36.

Head 40 includes Z-axis actuator 41 (see FIG. 5) that moves suction nozzle 45 in a Z-axis (up-down) direction, and 0-axis actuator 42 (see FIG. 5) that rotates suction nozzle 45 about the Z-axis. Head 40 can pick up the component by causing a negative pressure source to communicate with a suction port of suction nozzle 45 to apply a negative pressure to the suction port. In addition, head 40 can release the pickup of the component by causing a positive pressure source to communicate with the suction port of suction nozzle 45 to apply a positive pressure to the suction port. Head 40 may be a head including single suction nozzle 45 or may be a rotary head including multiple suction nozzles 45 arranged at equal intervals along an outer circumference of a columnar head main body. As a member for holding the component, a mechanical chuck or an electromagnet may be used instead of suction nozzle 45.

Part camera 23 is installed on base 11. Part camera 23 images the component, which is picked up by suction nozzle 45, from below when the component passes above part camera 23 to generate a captured image of the component, and outputs the generated captured image to control device 60 (see FIG. 5).

Mark camera 50 is attached to X-axis slider 32 and is caused to move in the X-axis direction and the Y-axis direction together with head 40 by head moving device 30. Mark camera 50 images an imaging target object from above to generate a captured image, and outputs the generated captured image of the imaging target object to control device 60 (see FIG. 5). Examples of the imaging target object of mark camera 50 include a component held on tape 72 fed out by feeder 70, a mark attached to board S. a component mounted on board S, and solder printed on a circuit wiring of board S.

As illustrated in FIG. 2, mark camera 50) includes illumination section 51 and camera main body 58. Illumination section 51 includes housing 52, epi-illumination 53, half-silvered mirror 54, side-illumination 55, and illumination controller 57 (see FIG. 5).

Housing 52 is a cylindrical member, which is open on a lower surface thereof, and is attached to a lower portion of camera main body 58. Epi-illumination 53 is provided on an inner side surface of housing 52. Epi-illumination 53 is an illumination in which multiple light sources having different colors, for example, as illustrated in FIG. 3, red LED 53a that emits single color of red (R), green LED 53b that emits single color of green (G), and blue LED 53c that emits single color of blue (B) are arranged in the same number or substantially the same number on rectangular support plate 53d. Each of LEDs 53a to 53c is LED in which a hemispherical lens is attached to a quadrangular base on which a light emitting element is arranged at the center thereof, to cover the light emitting element. In the present embodiment, as illustrated in FIG. 3, one of blue LEDs 53c is located at the center of the arrangement. This is because a light amount of blue LED 53c is weaker than a light amount of red LED 53a and green LED 53b. A shortage of the light amount in illuminating the target object can be covered to suppress the variation in the light amount for each color by locating one of blue LEDs 53c at the center of the arrangement.

Half-silvered mirror 54 is provided to be oblique inside housing 52. Half-silvered mirror 54 reflects horizontal-direction light emitted from each of LEDs 53a. 53b, and 53c of epi-illumination 53 downward. Half-silvered mirror 54 transmits the light from below toward camera main body 58.

Side-illumination 55 is provided in the vicinity of a lower opening of housing 52 in a horizontal manner. In side-illumination 55, multiple light sources having different colors, for example, as illustrated in FIG. 4, red LED 55a, green LED 55b, and blue LED 55c are arranged in the same number or substantially the same number on ring-shaped support plate 55d, and apply the light downward. Each of LEDs 55a to 55c is LED in which a hemispherical lens is attached to a quadrangular base on which a light emitting element is arranged at the center thereof, to cover the light emitting element. Diffusion plate 56 is provided below side-illumination 55 in housing 52. The light emitted from epi-illumination 53 and the light emitted from side-illumination 55 are finally applied onto the target object after the light is diffused at this diffusion plate 56.

Illumination controller 57 is, for example, a controller that has independent switching elements individually for LEDs 53a to 53c of epi-illumination 53 and LEDs 55a to 55c of side-illumination 55 and that can independently change the brightness of each LED in steps by controlling the switching of the switching elements using pulse width modulation (PWM).

Camera main body 58 is a monochrome camera that generates a monochrome captured image based on the received light. Camera main body 58 includes an optical system, such as a lens (not illustrated), and a monochrome imaging element (for example, monochrome CCD). When the light, which is emitted from epi-illumination 53 and side-illumination 55 and reflected by the target object, passes through half-silvered mirror 54 and reaches camera main body 58, camera main body 58 receives the light to generate the captured image.

Although respective wavelength areas of colors of R, G, and B are not particularly limited, for example, R may be from 590 to 780 nm, G may be from 490 to 570 nm, and B may be from 400 to 490 nm.

Feeder 70 includes reel 71 around which tape 72 is wound and a tape feeding mechanism that unwinds tape 72 from reel 71 to feed tape 72 to component supply position 74a. Multiple accommodation recessed portions 73 are provided in a front surface of tape 72 at equal intervals along a longitudinal direction of tape 72. The component is accommodated in each of accommodation recessed portions 73. These components are protected by a film that covers the front surface of tape 72. When the film is peeled off in component supply position 74a, tape 72 is in a state where the component is exposed. The component fed out to component supply position 74a is picked up by suction nozzle 45.

As illustrated in FIG. 5, control device 60 is configured as a microprocessor including CPU 61 as a main element, and includes ROM 62, storage 63 (for example, HDD or SSD), RAM 64, and input/output interface 65 in addition to CPU 61. These elements are electrically connected to each other via bus 66. Control device 60 receives the input of an image signal from mark camera 50, an image signal from part camera 23, or the like via input/output interface 65. Meanwhile, a control signal to board conveyance device 22, a driving signal to X-axis actuator 33, a driving signal to Y-axis actuator 37, a driving signal to Z-axis actuator 41, a driving signal to θ-axis actuator 42, a control signal to part camera 23, a control signal to mark camera 50, a control signal to feeder 70, or the like are output from control device 60 via input/output interface 65.

Next, the operation of component mounting machine 10 of the present embodiment will be described. First, a mounting operation in which component mounting machine 10 mounts the component on board S will be described. A routine of the mounting operation is stored in storage 63, and is started after a production job (data in which an order of mounting the components or target mounting positions of the components are stored) is input from a management device (not illustrated). When the mounting operation is started, CPU 61 causes suction nozzle 45 of head 40 to pick up the component supplied from feeder 70. Specifically, CPU 61 causes X-axis actuator 33 and Y-axis actuator 37 to move suction nozzle 45 directly above a component pickup position of a desired component. Next, CPU 61 causes Z-axis actuator 41 and the negative pressure source (not illustrated), to lower suction nozzle 45, and supplies the negative pressure to suction nozzle 45. As a result, the desired component is picked up by a tip portion of suction nozzle 45. Thereafter. CPU 61 lifts suction nozzle 45, and causes X-axis actuator 33 and Y-axis actuator 37 to move suction nozzle 45 that has picked up the component at the tip thereof to above the target mounting position of board S. Then, at the predetermined position. CPU 61 lowers suction nozzle 45 and causes the positive pressure source (not illustrated) to supply the atmospheric pressure to suction nozzle 45. As a result, the component picked up by suction nozzle 45 is separated and mounted at the predetermined position on board S. Another component to be mounted on board S is mounted on board S in the same manner, and when the mounting of all the components is completed. CPU 61 executes component presence/absence inspection. Then. CPU 61 causes board conveyance device 22 to feed out board S downstream.

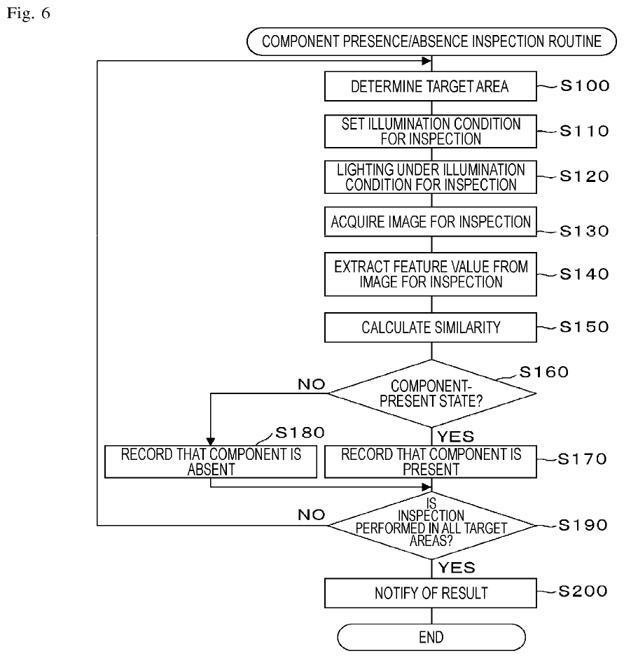

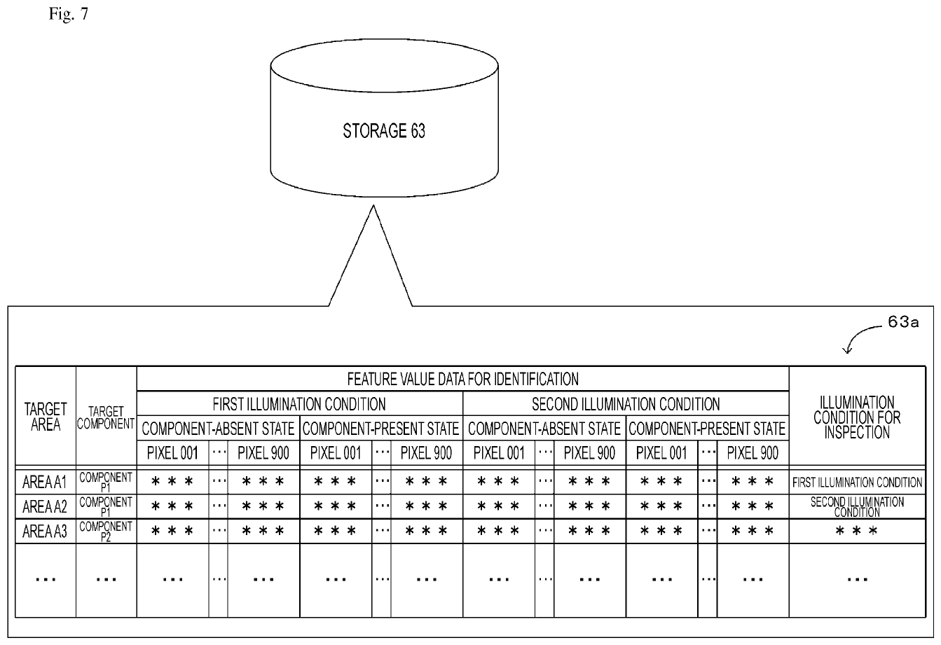

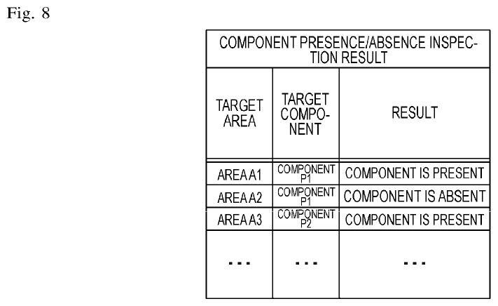

Next, the component presence/absence inspection executed by component mounting machine 10 will be described with reference to FIGS. 6 to 8. FIG. 6 is a flowchart illustrating an example of a component presence/absence inspection routine. FIG. 7 is a diagram illustrating an example of data for inspection 63a, and FIG. 8 is a diagram illustrating a component presence/absence inspection result table. Here, data for inspection 63a is data in which the target area, a target component, feature value data for identification, and the illumination condition for inspection are stored in association with each other. The present routine is stored in storage 63, and is started after the mounting of the component on board S is completed in component mounting machine 10. In the present embodiment, a state where the target component is not mounted in the target area (state where the component is absent in the target area) is referred to as a component-absent state, and a state where the target component is mounted in the target area (state where the component is present in the target area) is referred to as a component-present state. In the present embodiment, lighting of only side-illumination 55 by illumination section 51 is referred to as a first illumination condition, and lighting of only epi-illumination 53 by illumination section 51 is referred to as a second illumination condition. Under the first illumination condition and the second illumination condition, board S is irradiated with the light at invariable illumination intensity.

When the present routine is started. CPU 61 determines the target area (S100). Specifically. CPU 61 determines the target component based on the production job, acquires the target mounting position at which the target component is mounted from the production job, and sets the target area based on the size, the shape, and the target mounting position of the target component. Subsequently. CPU 61 sets the illumination condition for inspection (S110). Specifically. CPU 61 reads out the illumination condition for inspection corresponding to the target area determined in S100 from data for inspection 63a in FIG. 7. For example, in a case where an area A1 is set as the target area in S100. CPU 61 sets the first illumination condition as the illumination condition for inspection, and in a case where an area A2 is set as the target area in S100. CPU 61 sets the second illumination condition as the illumination condition for inspection. Whether the illumination condition for inspection corresponding to the target area is the first illumination condition or the second illumination condition is determined in a pre-inspection processing routine described later.

Subsequently. CPU 61 lights illumination section 51 under the illumination condition for inspection (S120). Specifically, in a case where the first illumination condition is set as the illumination condition for inspection in S110, CPU 61 outputs a signal of the first illumination condition to mark camera 50, and in a case where the second illumination condition is set as the illumination condition for inspection in S110. CPU 61 outputs a signal of the second illumination condition to mark camera 50. When these signals are input, illumination controller 57 provided in mark camera 50 causes illumination section 51 to irradiate board S with the light under the illumination condition for inspection. Subsequently. CPU 61 acquires an image for inspection (S130). Specifically. CPU 61 causes camera main body 58 provided in mark camera 50 to capture an image of the target area set in S110. Then, CPU 61 stores the image for inspection obtained by compressing the image to a predetermined size in storage 63. The size of the image for inspection is set to an invariable size (invariable number of pixels) regardless of the size of the target area or the component.

Subsequently. CPU 61 extracts feature value data from the image for inspection (S140). Here, the feature value data is a feature value of the image and is, for example, luminance of multiple pixels included in the image.

Subsequently. CPU 61 calculates a similarity (S150). Specifically. CPU 61 calculates the similarity between the image for inspection and the image of the component-absent state and also calculates the similarity between the image for inspection and the image of the component-present state using the feature value data of the image for inspection extracted in S140 and the feature value data for identification corresponding to the illumination condition for inspection stored in advance in data for inspection 63a. The method of calculating the feature value data for identification and the method of calculating the similarity will be described in the pre-inspection processing routine described later.

Subsequently. CPU 61 determines whether a state of the target area is the component-present state (S160). Specifically, in a case where the similarity between the image for inspection and the image of the component-present state is larger than the similarity between the image for inspection and the image of the component-absent state. CPU 61 performs an affirmative determination, and in a case where the similarity between the image for inspection and the image of the component-present state is equal to or smaller than the similarity between the image for inspection and the image of the component-absent state. CPU 61 performs a negative determination. In a case where an affirmative determination is performed in S160. CPU 61 records “component is present” in the column of the result corresponding to the current target area in the component presence/absence inspection result table (FIG. 8) of storage 63 (S170). On the other hand, in a case where a negative determination is performed in S160. CPU 61 records “component is absent” in the column of the result corresponding to the current target area in the component presence/absence inspection result table (S180). After S170 or S180. CPU 61 determines whether the inspection is performed for all the target areas (S190). In a case where a negative determination is performed in S190. CPU 61 returns to S100 again, determines an uninspected target area, and executes the processing of S110 and thereafter. On the other hand, in a case where an affirmative determination is performed in S190. CPU 61 notifies of the result (S200). Specifically. CPU 61 displays the component presence/absence inspection result table on a display device (not illustrated) provided in component mounting machine 10. After S200. CPU 61 terminates the present routine.

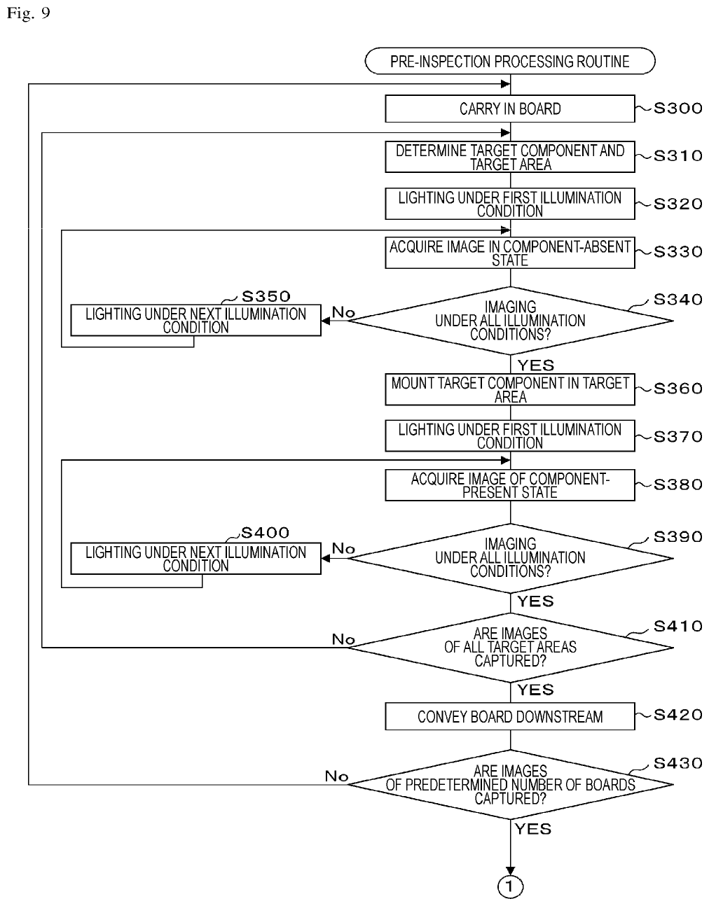

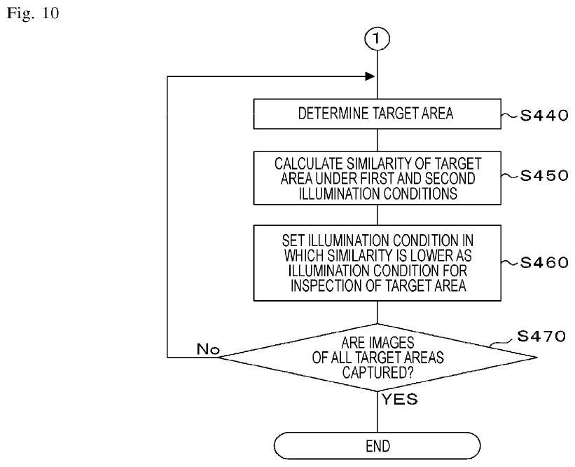

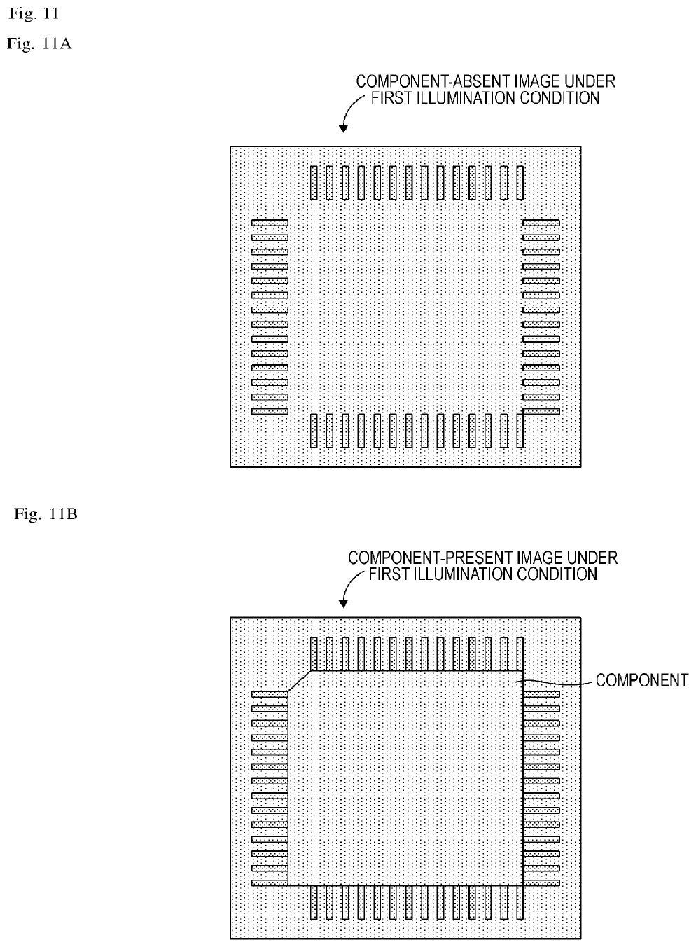

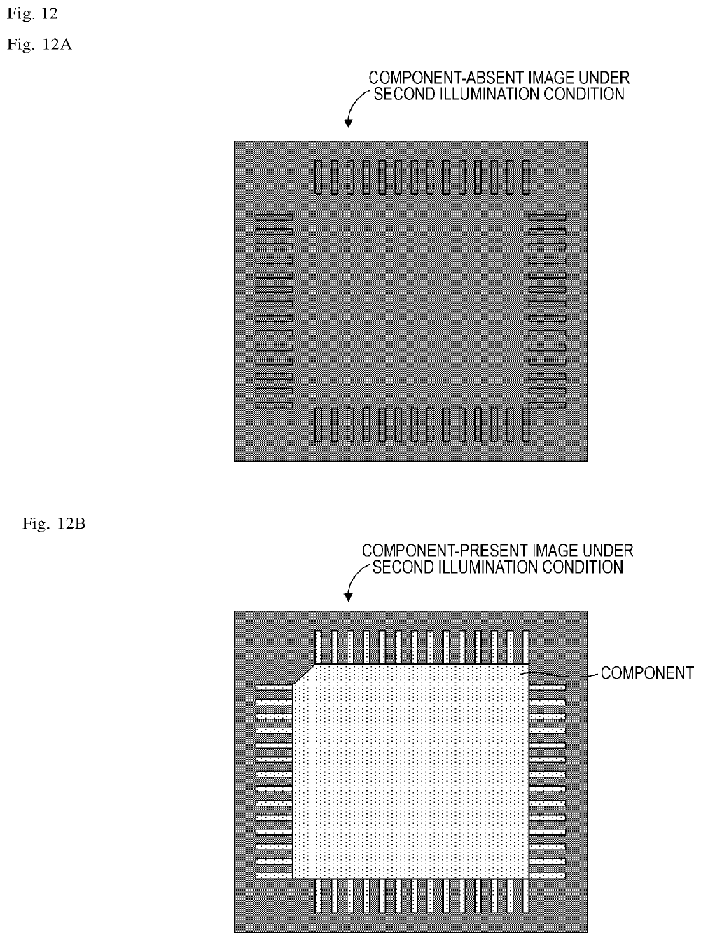

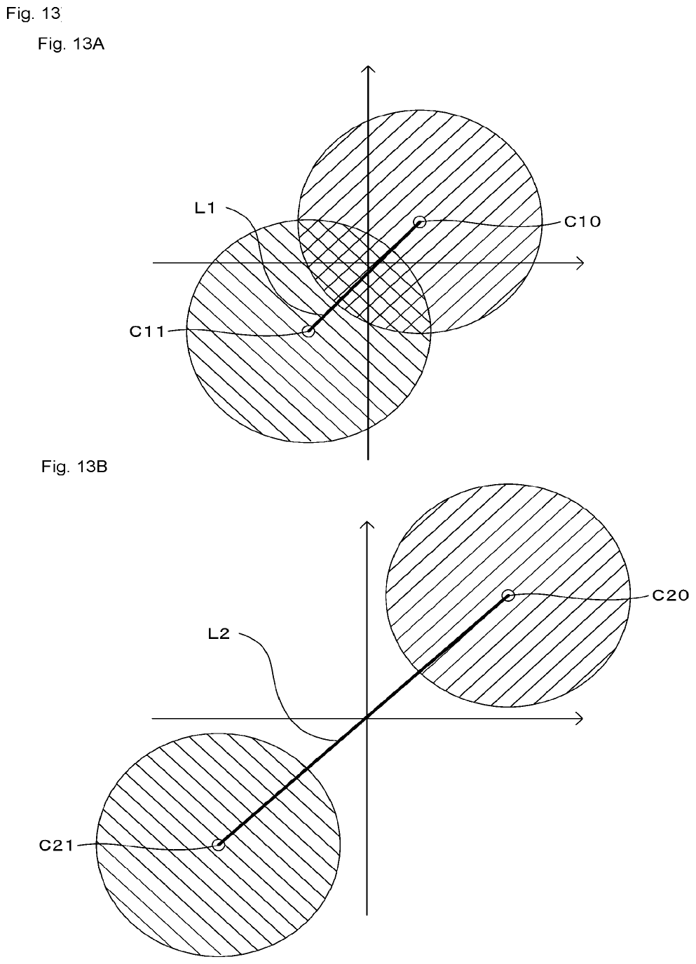

Next, the pre-inspection processing executed prior to the component presence/absence inspection will be described with reference to FIGS. 9 to 13. FIGS. 9 and 10 are flowcharts illustrating an example of the pre-inspection processing routine. FIG. 11 is a diagram illustrating an example of the image obtained by imaging the target area under the first illumination condition. FIG. 12 is a diagram illustrating an example of the image obtained by imaging the target area under the second illumination condition, and FIG. 13 is a diagram illustrating the similarity. The present routine is stored in storage 63, and is executed after an instruction to start the pre-inspection processing is input from an operator, and the production job is input from the management device (not illustrated). Further, the present routine is executed while performing the component mounting processing by component mounting machine 10 in a trial manner.

When the present routine is started. CPU 61 carries in board S (S300). Specifically. CPU 61 controls board conveyance device 22 so that board S is conveyed to a predetermined position in component mounting machine 10. Subsequently. CPU 61 determines the target component and the target area based on the production job (S310). Specifically. CPU 61 sets one of the components to be mounted by component mounting machine 10 as the target component, and sets an area of board S in which the target component is to be mounted as the target area. Subsequently. CPU 61 lights illumination section 51 under the first illumination condition (S320). Specifically, CPU 61 outputs the signal of the first illumination condition to mark camera 50. When the signal of the first illumination condition is input, illumination controller 57 provided in mark camera 50) causes illumination section 51 to irradiate board S with the light only using side-illumination 55.

Subsequently, CPU 61 acquires the image of the component-absent state (S330). Specifically. CPU 61 causes camera main body 58 provided in mark camera 50 to capture the image of the target area set in S310. Then, CPU 61 stores the image of the component-absent state obtained by compressing the image to a predetermined size in storage 63. The size of the image of the component-absent state is set to an invariable size regardless of the size of the target area or the target component, and is the same size as the image for inspection described above. Here, an example of the image of the component-absent state obtained under the first illumination condition is illustrated in FIG. 11A.

Subsequently, CPU 61 determines whether the image of the component-absent state is acquired under all the illumination conditions (S340). In a case where a negative determination is performed in S340, CPU 61 lights illumination section 51 under the next illumination condition (second illumination condition) (S350), and acquires the image of the component-absent state in that case (S330). Specifically, CPU 61 outputs the signal of the second illumination condition to mark camera 50 so that board S is irradiated with the light only using epi-illumination 53. When the signal of the second illumination condition is input, illumination controller 57 provided in mark camera 50) causes illumination section 51 to irradiate board S with the light only using epi-illumination 53. In this state, CPU 61 causes camera main body 58 provided in mark camera 50) to capture the image under the second illumination condition, and stores the image of the component-absent state, which is obtained by compressing the image in storage 63. Here, an example of the image of the component-absent state obtained under the second illumination condition is illustrated in FIG. 12A.

On the other hand, in a case where an affirmative determination is performed in S340, CPU 61 mounts the target component in the target area (S360). Specifically, CPU 61 controls head moving device 30 and head 40 so that the target component is mounted in the target area of board S. Next, CPU 61 sets the illumination condition to the first illumination condition (S370). S370 is the same processing as S320. Subsequently. CPU 61 acquires the image of the component-present state (S380). Specifically, CPU 61 causes camera main body 58 provided in mark camera 50 to capture the image of the target area set in S310 and stores the image of the component-present state, which is obtained by compressing the image to the same size as the image for inspection, in storage 63. Here, an example of the image of the component-present state obtained under the first illumination condition is illustrated in FIG. 11B.

Subsequently. CPU 61 determines whether the image of the component-present state is acquired under all the illumination conditions (S390). In a case where a negative determination is performed in S390. CPU 61 lights illumination section 51 under the next illumination condition (second illumination condition) (S400), and stores the image of the component-present state in storage 63 (S380). S400 is the same processing as S350. Here, an example of the image of the component-present state obtained under the second illumination condition is illustrated in FIG. 12B.

On the other hand, in a case where an affirmative determination is performed in S390. CPU 61 determines whether the images of all the target areas are captured (S410). Specifically, in a case where the processing of S310 to S400 is executed for all the target areas corresponding to the component (target component) mounted by its machine (component mounting machine 10 including control device 60 provided with CPU 61). CPU 61 performs an affirmative determination, and in the opposite case. CPU 61 performs a negative determination. In a case where a negative determination is performed in S410. CPU 61 returns to S310 again, determines the next target component and target area, and executes the subsequent processing and thereafter. On the other hand, in a case where an affirmative determination is performed in S410. CPU 61 conveys board S downstream (S420). Specifically. CPU 61 causes board conveyance device 22 to feed out board S downstream. Subsequently. CPU 61 determines whether images of a predetermined number of board S are captured (S430). Specifically, in a case where CPU 61 performs the processing of S300 to S420 on a predetermined number (for example. 10) of boards S. CPU 61 performs an affirmative determination, and in the opposite case. CPU 61 performs a negative determination. In a case where a negative determination is performed in S430. CPU 61 returns to S300 again.

On the other hand, in a case where an affirmative determination is performed in S430. CPU 61 determines one target area on board S (S440), and calculates the similarity under the first illumination condition and the similarity under the second illumination condition for the target area (S450). The similarity under the first illumination condition is the similarity between the feature value data for identification of the component-absent image under the first illumination condition in the target area (target area determined in S440) and the feature value data for identification of the component-present image under the first illumination condition in the target area. The similarity under the second illumination condition is the similarity between the feature value data for identification of the component-absent image under the second illumination condition in the target area and the feature value data for identification of the component-present image under the second illumination condition in the target area.

The feature value data is, for example, the luminance of the pixels included in the image. Even in a case where the same component is mounted and captured at the same position, the feature value data may vary in the obtained image depending on a mounting deviation or a solder application state. Therefore, a predetermined number of the component-absent images and the component-present images under each illumination condition in the target area are used instead of one component-absent image and one component-present image. Then, the feature value data for identification of the component-absent image under the first illumination condition is obtained from the feature value data of a predetermined number of the component-absent images under the first illumination conditions, and the feature value data for identification of the component-present image under the first illumination condition is obtained from the feature value data of a predetermined number of the component-present images under the first illumination conditions. The feature value data for identification may be, for example, an average value or a median value of a predetermined number of the feature value data. The feature value data for identification of the component-absent image and the component-present image under the second illumination condition are also obtained in the same manner. In this way, the influence of the variation of the feature value data can be suppressed by obtaining feature value data for identification. In a case where the size of the image is 900 pixels, the feature value data has 900 dimensions, but for convenience, the description will be made assuming that the feature value data has two dimensions. The similarity under the first illumination condition can be represented by a length of a distance between two points when the feature value data for identification of the component-absent image under the first illumination condition in the target area and the feature value data for identification of the component-present image under the first illumination condition in the target area are displayed as points on two-dimensional coordinates. The similarity is lower as the distance between two points is longer, and is higher as the distance is shorter.

FIG. 13 is a diagram illustrating the similarity. In FIG. 13A, the similarity under the first illumination condition is represented by line segment L1 connecting feature value data for identification C10 of the component-absent image obtained by imaging the target area under the first illumination condition and feature value data for identification C11 of the component-present image obtained by imaging the same target area under the first illumination condition. In FIG. 13B, the similarity under the second illumination condition is represented by line segment L2 connecting feature value data for identification C20 of the component-absent image obtained by imaging the same target area under the second illumination condition and feature value data for identification C21 of the component-present image obtained by imaging the same target area under the second illumination condition. A circle surrounding each of feature value data for identification C10 and C20 indicates the variation of the feature value data of a predetermined number of the component-absent images, and a circle surrounding each of feature value data for identification C11 and C21 indicates the variation of the feature value data of a predetermined number of the component-present images.

Subsequently. CPU 61 sets the illumination condition in which the similarity is lower out of the similarity under the first illumination condition and the similarity under the second illumination condition as the illumination condition for inspection of the target area, and writes the illumination condition into data for inspection 63a of the storage (S460). For example, in the case of FIG. 13, the similarity under the first illumination condition is represented by line segment L1, the similarity under the second illumination condition is represented by line segment L2, and the similarity under the second illumination condition is lower because L1<L2. Therefore, the second illumination condition is set as the illumination condition for inspection of the target area.

Subsequently. CPU 61 determines whether the illumination condition for inspection is set for all the target areas of board S (S470), and in a case where a negative determination is performed. CPU 61 returns to S440 to determine the next target area, and then executes the processing of S450 to S470. On the other hand, in a case where an affirmative determination is performed in S470. CPU 61 terminates the present routine. As a result, in data for inspection 63a, all the columns of the illumination condition for inspection corresponding to the inspection area are filled.

Here, a correspondence relationship between the elements of the present embodiment and the elements of the present disclosure will be clarified. Component mounting machine 10 of the present embodiment corresponds to a component mounting machine of the present disclosure, illumination section 51 provided in mark camera 50) corresponds to an illumination section, camera main body 58 provided in mark camera 50) corresponds to an imaging section, and control device 60 corresponds to a control section.

In component mounting machine 10 described in detail above, when the illumination condition for inspection is set based on the similarity, the illumination condition in which the similarity is lowest among multiple different illumination conditions is set as the illumination condition for inspection. In a case where the illumination condition in which the similarity is high is set as the illumination condition for inspection, it may be impossible to perform, with high accuracy, a determination whether the image for inspection is close to the image of the component-present state or the image of the component-absent state. Here, since the illumination condition in which the similarity is lowest is set as the illumination condition for inspection, the component presence/absence inspection can be performed with high accuracy. Further, since it is not necessary for an operator to set the illumination condition for inspection, a work burden is not imposed on the operator. Therefore, an appropriate illumination condition for inspection can be easily set.

Further, in component mounting machine 10, illumination section 51 includes side-illumination 55 and epi-illumination 53, and the illumination conditions include two illumination conditions, the first illumination condition in which board S is irradiated with the light only using side-illumination 55 and the second illumination condition in which board S is irradiated with the light only using epi-illumination 53. Therefore, it is possible to set a more appropriate illumination condition for inspection by selectively using side-illumination 55 and epi-illumination 53.

Further, in component mounting machine 10, the image of the component-absent state and the image of the component-present state are images obtained by compressing the image captured by camera main body 58 of mark camera 50 to the same size, and the similarity is calculated based on the feature value data extracted from each of the image of the component-absent state and the image of the component-present state. Therefore, it is easy to calculate the similarity between the image of the component-absent state and the image of the component-present state. The sizes of the image of the component-absent state and the image of the component-present state are invariable sizes regardless of the size of the target component. Therefore, since the similarity can be calculated by extracting the feature value data from the predetermined positions of the image of the component-absent state and the image of the component-present state, it is easier to calculate the similarity.

The present disclosure is not limited in any way to the embodiment described above, and it is needless to say that the present disclosure can be implemented in various forms without departing from the technical scope of the present disclosure.

In the embodiment described above, the illumination condition for inspection is set to the illumination condition in which the similarity between the image of the component-absent state and the image of the component-present state is lowest among multiple different illumination conditions, but the configuration is not limited to this. For example, the illumination condition for inspection may be set to an illumination condition in which the similarity between the image of the component-absent state and the image of the component-present state is lower than a predetermined similarity. In this case, the predetermined similarity is, for example, the following similarity. That is, as in FIG. 13, the predetermined similarity can be represented by a length of line segment Lt connecting the feature value data for identification of the component-absent state and the feature value data for identification of the component-present state when the feature value data for identification of the image of the component-absent state and the feature value data for identification of the image of the component-present state are displayed as points on two-dimensional coordinates. The length of line segment Lt is a length such that a range in which the feature value data of the image of the component-absent state varies and a range in which the feature value data of the image of the component-present state varies do not overlap. In a case where there are multiple illumination conditions in which the similarity between the image of the component-absent state and the image of the component-present state is lower than the predetermined similarity, the illumination condition in which the similarity is lowest among the illumination conditions in which the similarity is lower than the predetermined similarity may be set as the illumination condition for inspection.

In the embodiment described above, in the pre-inspection processing, board S is irradiated with the light under the first illumination condition and the second illumination condition to acquire the image of the component-absent state and the image of the component-present state, but the configuration is not limited to this. For example, in a case where a third condition in which both side-illumination 55 and epi-illumination 53 are lighted is selectable as the illumination condition, board S may be irradiated with the light under the first illumination condition and the third illumination condition to acquire the image of the component-absent state and the image of the component-present state, board S may be irradiated with the light under the second illumination condition and the third illumination condition to acquire the image of the component-absent state and the image of the component-present state, and board S may be irradiated with the light under the first illumination condition, the second illumination condition, and the third illumination condition to acquire the image of the component-absent state and the image of the component-present state.

In the embodiment described above, the component presence/absence inspection is executed, but component position inspection may be executed instead of the component presence/absence inspection. In the component position inspection, after it is determined that the component is present in S160 and “component is present” is stored in S170, a positional deviation amount of the component is calculated, whether the positional deviation amount is within an allowable range is determined, it is determined that the mounting state is good in a case where an affirmative determination is performed, and it is determined that the mounting state is bad in a case where a negative determination is performed.

In the embodiment described above, the illumination intensity is invariable under the first illumination condition and the second illumination condition, but the configuration is not limited to this. For example, the illumination condition may include a high illumination intensity condition of the illumination intensity and a low illumination intensity condition of the illumination intensity. In this way, it is possible to set a more appropriate illumination condition for inspection by changing the illumination intensity.

In the embodiment described above, the illumination condition may include multiple conditions using one or more LEDs selected from LEDs 53a to 53c and 55a to 55c. In this way, it is possible to set a more appropriate illumination condition for inspection by changing the color of the light source. In this case, for example, red LED 55a of side-illumination 55 and red LED 53a of epi-illumination 53 may be lighted under the first illumination condition, green LED 55b of side-illumination 55 and green LED 53b of epi-illumination 53 may be lighted under the second illumination condition, or blue LED 55c of side-illumination 55 and blue LED 53c of epi-illumination 53 may be lighted under the third illumination condition.

In the embodiment described above, the feature value data for identification is a representative value (for example, an average value or a median value) of a predetermined number of the feature value data, but the configuration is not limited to this. For example, the feature value data for identification may be feature value data extracted from one image.

In the embodiment described above, illumination section 51 includes red LEDs 53a and 55a, green LEDs 53b and 55b, and blue LEDs 53c and 55c, but the configuration is not limited to this. For example, white LED may be provided, or LED of another color may be provided.

In the embodiment described above, the similarity is represented by the distance between two points when the feature value data for identification of the image of the component-absent state and the feature value data for identification of the image of the component-present state are displayed as points on the two-dimensional coordinates, but the configuration is not limited to this. For example, the similarity may be represented by a total value obtained by calculating, for each pixel, an absolute value of a difference between the feature value data for identification of the image of the component-absent state and the feature value data for identification of the image in the component-present state, and adding up the absolute values of the differences for all pixels. In this case, the similarity is lower as the total value is larger, and is higher as the total value is smaller. Alternatively, the similarity may be represented by a total value obtained by calculating, for each pixel, a value obtained by squaring a difference between the feature value data for identification of the image of the component-absent state and the feature value data for identification of the image in the component-present state, and adding up the values obtained by squaring the difference for all pixels. In this case, the similarity is lower as the total value is larger, and is higher as the total value is smaller. Alternatively, the similarity may be represented by a correlation value between the feature value data for identification of the image of the component-absent state and the feature value data for identification of the image of the component-present state.

The disclosed component mounting machine may be configured as follows.

In the component mounting machine of the present disclosure, the illumination section may include side-illumination and epi-illumination, and the illumination conditions may include at least two of a first illumination condition in which the board is irradiated with light only using the side-illumination, a second illumination condition in which the board is irradiated with light only using the epi-illumination, and a third illumination condition in which the board is irradiated with light using both the side-illumination and the epi-illumination. In this way, it is possible to set a more appropriate illumination condition for inspection by selectively using side-illumination 55 and epi-illumination 53.

In the component mounting machine of the present disclosure, the illumination section may be configured to change illumination intensity, and the illumination conditions may include a condition in which the illumination intensity is high and a condition in which the illumination intensity is low. In this way, it is possible to set a more appropriate illumination condition for inspection by changing the illumination intensity.

In the component mounting machine of the present disclosure, the illumination section may include light sources having different colors, and the illumination conditions may include multiple conditions in which one or more light sources selected from among the light sources provided in the illumination section are used. In this way, it is possible to set a more appropriate illumination condition for inspection by changing the color of the light source. In this case, the light sources having different colors may be a red light source, a green light source, and a blue light source.

In the component mounting machine of the present disclosure, the image of the component-absent state and the image of the component-present state may be images obtained by compressing the image captured by the imaging section to the same size, and the similarity may be calculated based on a feature value extracted from each of the image of the component-absent state and the image of the component-present state. In this way, it is easy to calculate the similarity between the image of the component-absent state and the image of the component-present state. In this case, sizes of the image of the component-absent state and the image of the component-present state may be invariable sizes regardless of a size of the target component. In this way, for example, the similarity can be calculated by extracting the feature value from the predetermined positions of the image of the component-absent state and the image of the component-present state. Therefore, it is easier to calculate the similarity.

### INDUSTRIAL APPLICABILITY

The present disclosure can be applied in the manufacturing industry for the component mounting machine and the like.

### REFERENCE SIGNS LIST

10: component mounting machine, 11: base, 12: casing, 22: board conveyance device, 23: part camera, 24: nozzle station, 30: head moving device, 31: X-axis guide rail, 32: X-axis slider, 33: X-axis actuator, 35: Y-axis guide rail, 36: Y-axis slider, 37: Y-axis actuator, 40: head, 41: Z-axis actuator, 42: θ-axis actuator, 45: suction nozzle, 50: mark camera, 51: illumination section, 52: housing, 53: epi-illumination, 53a, 55a: red LED, 53b, 55b: green LED, 53c, 55c: blue LED, 53d, 55d: support plate, 54: half-silvered mirror, 55: side-illumination, 56: diffusion plate, 57: illumination controller, 58: camera main body, 60: control device, 61: CPU, 62: ROM, 63: storage, 63a: data for inspection, 64: RAM, 65: input/output interface, 66: bus, 70: feeder, 71: reel, 72: tape, 73: accommodation recessed portion, 74a: component supply position, S: board

1. A component mounting machine for mounting components on a board, the component mounting machine comprising:
an illumination section configured to irradiate the board with light under multiple different illumination conditions;
an imaging section configured to capture an image of the board from above the board; and
a control section configured to, in a case where one of the components is defined as a target component, an area in which the target component is mounted on the board is defined as a target area, a state where the target component is absent in the target area is defined as a component-absent state, and a state where the target component is present in the target area is defined as a component-present state, cause the illumination section and the imaging section to capture an image of the component-absent state and an image of the component-present state under the multiple different illumination conditions, calculate a similarity between the image of the component-absent state and the image of the component-present state for each illumination condition, and set an illumination condition for inspection used in execution of inspection of the target component, based on the similarity,
wherein the control section is configured to, when setting the illumination condition for inspection based on the similarity, among the multiple different illumination conditions, set an illumination condition in which the similarity is lower than a predetermined similarity as the illumination condition for inspection, set an illumination condition in which the similarity is lowest as the illumination condition for inspection, or set an illumination condition in which the similarity is lower than the predetermined similarity and is lowest as the illumination condition for inspection.

2. The component mounting machine according to claim 1,
wherein the illumination section includes side-illumination and epi-illumination, and
the illumination conditions include at least two of a first illumination condition in which the board is irradiated with light only using the side-illumination, a second illumination condition in which the board is irradiated with light only using the epi-illumination, and a third illumination condition in which the board is irradiated with light using both the side-illumination and the epi-illumination.

3. The component mounting machine according to claim 1,
wherein the illumination section is configured to change illumination intensity, and the illumination conditions include a condition in which the illumination intensity is high and a condition in which the illumination intensity is low.

4. The component mounting machine according to claim 1,
wherein the illumination section includes light sources having different colors, and
the illumination conditions include multiple conditions in which one or more light sources selected from among the light sources provided in the illumination section are used.

5. The component mounting machine according to claim 4,
wherein the light sources having different colors are a red light source, a green light source, and a blue light source.

6. The component mounting machine according to claim 1,
wherein the image of the component-absent state and the image of the component-present state are images obtained by compressing the image captured by the imaging section to the same size, and
the similarity is calculated based on a feature value extracted from each of the image of the component-absent state and the image of the component-present state.

7. The component mounting machine according to claim 6,
wherein sizes of the image of the component-absent state and the image of the component-present state are invariable sizes regardless of a size of the target component.
